(19) United States
(12) Patent Application Publication
(10) Pub. No.: US 2008/0036484 A1
(43) Pub. Date: Feb. 14, 2008

(54) Test probe and manufacturing method thereof

(75) Inventor: Chae Yoon Lee, Busan (KR)

Correspondence Address: HYUN JONG PARK, 41 WHITE BIRCH ROAD, REDDING, CT, 06896-2209, US

(73) Assignee: Leeno Industrial Inc.

(21) Appl. No.: 11/708,311

(22) Filed: Feb. 20, 2007

(30) Foreign Application Priority Data
Aug. 10, 2006 (KR) 10-2006-0075667
Nov. 9, 2006 (KR) 10-2006-0110370

(51) Int. Cl. G01R 1/067; H01R 43/00

(52) U.S. Cl. 324/761; 29/825

(57) ABSTRACT

Disclosed herein are a test probe and a method of manufacturing the test probe. The invention has a simple structure, thus affording ease of manufacture, and eliminates contact resistance during a test, thus enhancing the reliability of the test. The test probe includes a probe part which is provided on the upper portion of the probe and contacts a contact terminal of an object to be tested. A spring part, providing elastic force, extends integrally from the lower portion of the probe part, so that current flows from the object to the lower portion of the spring part. According to this invention, the spring part is integrally provided on the lower portion of the probe part, thus having a simple structure and affording ease of manufacture, and measuring current is transmitted directly from the probe part to the spring part, thus eliminating contact resistance and shortening the signal path, therefore enhancing the reliability of a test.

### FIELD OF THE INVENTION

The present invention relates generally to a test probe and a method of manufacturing the test probe and, more particularly, to a test probe and a method of manufacturing the test probe, in which a spring part providing elastic force extends integrally from the lower portion of a probe part contacting a contact terminal of an object to be tested.

### BACKGROUND OF THE INVENTION

Generally, a plurality of chips is installed in various kinds of electronic products. The chips play an important role in determining the performance of the electronic products.

The chips are integrated circuits which carry out various functions using the logic elements formed on thin and small wafers. Each chip conducts its function in response to an electric signal which is transmitted from a printed circuit board (PCB) through a bus to the chip.

The PCB comprises a thin substrate made of an insulator, such as epoxy or bakelite resin. Circuit wiring is formed on the substrate using a conductor, such as copper. Electronic components, including integrated circuits, resistors, and switches, are soldered on the circuit wiring, and thus the electronic components are mounted on the PCB.

A microchip is a chip which is made by densely integrating an electronic circuit of the PCB. Before the chip is mounted on an electronic product and the assembly is completed, the chip must undergo a testing process using test equipment so as to check whether the chip is normal or not.

As an example of the test method, a method of mounting the chip on a test socket and testing the chip has been proposed. In order to carry out the test while preventing the chip from being broken or damaged in the socket, a test probe has been mounted and used.

FIG. 1 is a view showing the state where an object is tested using a conventional test probe.

As shown in the drawing, a test socket 3 is mounted on a PCB 4, and an object to be tested, namely, a microchip 1, is placed on the socket 3. In such a state, the microchip 1 is tested.

A plurality of test probes 5 is mounted on the test socket 3, and a contact pin 6 is connected to the lower end of each probe 5.

The upper ends of the probes 5 contact several portions of the microchip to be tested. In such a state, current flows from the microchip through the body of each probe and the contact pin provided on the lower end of each probe to the PCB, so that the chip can be tested.

FIG. 2 is a sectional view showing the conventional test probe.

As shown in the drawing, the probe includes an outer cylinder 8, and a probe part 7 which is slidably installed in the outer cylinder 8. A contact pin 6 is provided on the lower end of the outer cylinder 8, and a compression coil spring 9 is accommodated in the outer cylinder 8 to elastically support the probe part 7.

When a microchip is tested by the probe having such a construction, the microchip to be tested is seated on the socket, and a pressing part mounted on the socket presses the microchip down, and thus the microchip contacts the probe part 7 of the probe.

However, the conventional probe is problematic in that current applied to the probe part is indirectly transmitted through the outer cylinder and the spring, so that contact resistance is increased, and thus the reliability of the test is lowered.

In order to solve the problem, Japanese Patent Laid-Open Publication No. 7-5200 and Korean U.M. Laid-Open Publication No. 1999-8144 proposed a method of reducing contact resistance.

However, the prior art has a complicated construction, so that it is difficult to manufacture. Further, the prior art adopts an indirect transmitting method through the outer cylinder, so that contact resistance may be increased or the elastic force of the spring may be lost due to over-current.

Further, since current applied to the probe part of the probe is transmitted through the outer cylinder and the spring to the PCB, the signal path is lengthened, so that the reliability of the test is poor.

### SUMMARY OF THE INVENTION

Accordingly, the present invention has been made keeping in mind the above problems occurring in the prior art, and an object of the present invention is to provide a test probe, which has a simple structure, thus affording ease of manufacture, and eliminates contact resistance during a test, thus enhancing the reliability of the test.

Another object of the present invention is to provide a method of manufacturing a test probe, which is capable of manufacturing a spring part integrated with a probe part.

In order to accomplish the above objects, the present invention provides a test probe including a probe part which is provided on an upper portion of the probe and contacts a contact terminal of an object to be tested, and a spring part which provides elastic force and extends integrally from a lower portion of the probe part, so that current flows from the object to a lower portion of the spring part.

Preferably, a lower plunger is coupled to the lower portion of the spring part, so that current flows from the object to a lower portion of the lower plunger. A locking step is provided along an outer circumferential surface of the probe part, and engages with a test socket.

The spring part comprises a coil spring made by forming a hollow part by boring the cylindrical probe part or drilling the upper or lower portion of the probe part, and cutting an outer circumferential surface of the hollow part at a predetermined lead angle.

Preferably, a guide shaft is provided in a center of the lower plunger and extends upwards, and a shaft hole is formed in an upper portion of the hollow part defined in the cylindrical probe part so that the guide shaft is inserted into the shaft hole.

The lower plunger includes a cylindrical body which is coupled to the spring part, and at least one contact protrusion which is provided on a lower portion of the cylindrical body and has a hemispherical shape or an inverted conical shape.

Further, in order to accomplish the above objects, the present invention provides a method of manufacturing a test probe including a probe part which is provided on an upper portion thereof and has a plurality of protrusions contacting a contact terminal of an object to be tested, and a spring part integrally provided on a lower portion of the probe part, the method including forming a hollow shaft by forming a hollow part in a solid shaft extending downwards from the cylindrical probe part, and cutting an outer circumferential surface of the hollow shaft at a predetermined lead angle, thus making a coil spring out of the outer circumferential surface of the hollow shaft.

The method includes coupling the lower plunger to a lower portion of the coil spring.

The forming the hollow shaft includes forming the hollow shaft by forming a hollow part passing through the cylindrical probe part, or by drilling an upper or lower portion of the cylindrical probe part.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a view showing the state where an object is tested using a conventional test probe;

FIG. 2 is a sectional view showing the conventional test probe;

FIGS. 3a and 3b are front views showing a test probe, according to the preferred embodiment of the present invention;

FIG. 4 is a sectional view showing the state where the test probe of the present invention is mounted to a test socket;

FIGS. 5a to 5c are front views showing a test probe equipped with a lower plunger, according to the preferred embodiment of the present invention;

FIGS. 6a and 6b are front views showing the shape of a spring part, according to the preferred embodiment of the present invention;

FIGS. 7a and 7b are front views showing the state where an elastic member is coupled to the spring part, according to the preferred embodiment of the present invention; and

FIGS. 8a and 8b are front views showing a contact protrusion provided on the lower plunger, according to the preferred embodiment of the present invention.

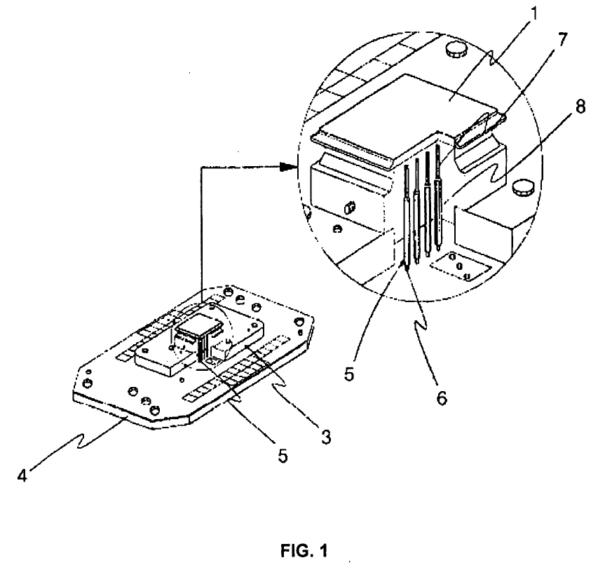

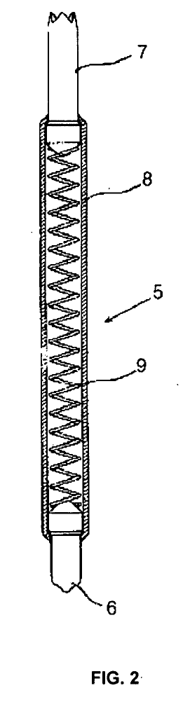

### DETAILED DESCRIPTION OF THE INVENTION

Reference now should be made to the drawings, in which the same reference numerals are used throughout the different drawings to designate the same or similar components.

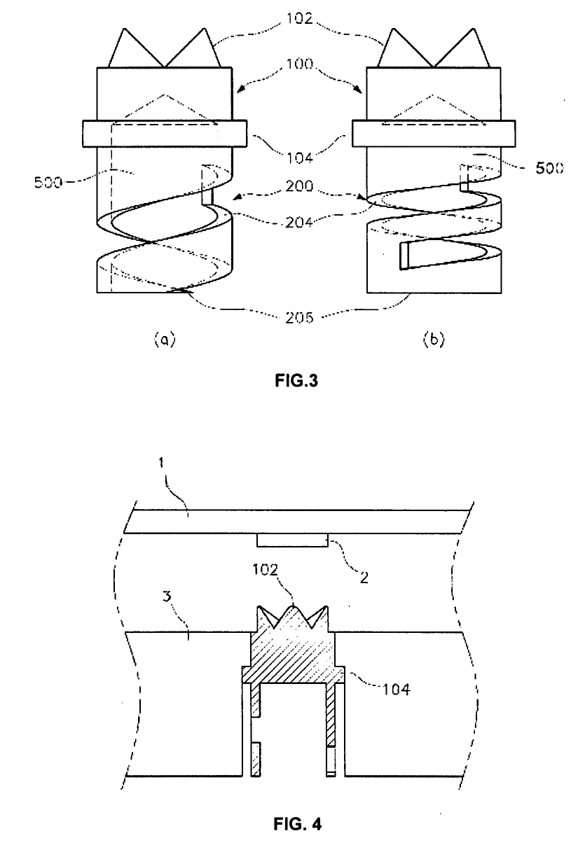

FIGS. 3a and 3b are front views showing a test probe, according to the preferred embodiment of the present invention.

As shown in the drawings, the test probe of the present invention has on the upper portion thereof a probe part 100 which contacts a contact terminal of an object to be tested. A spring part 200, providing elastic force, extends integrally from the lower portion of the probe part 100.

According to the present invention, the probe part 100 is integrated with the spring part 200, unlike the conventional probe. Thus, when current for a test flows, the current is transmitted directly from a microchip through the probe part 100 to the spring part 200 for testing of the microchip using a contact pin connected to the lower end of the probe. Therefore, the contact resistance of the probe itself can be eliminated.

Further, since the probe has a single structure, unlike the conventional probe, the height of the probe can be reduced. Thus, a signal path of current for a test is shortened.

Although not shown in the drawings, current flowing through the coil spring may be transmitted to a test device (not shown) of a PCB so as to test the microchip.

The probe part 100 is connected to the microchip. Since technology related to a protrusion 102 of the probe part 100 is already widely known, a detailed description of the protrusion 102 will be omitted.

Next, the spring part will be described in detail.

As shown in the drawings, the spring part 200 preferably comprises a coil spring which is made by boring the cylindrical probe part 100 or drilling the upper or lower portion of the probe part 100 to form a hollow part 500, and cutting the outer circumference of the hollow part 500 at a predetermined lead angle.

The lead angle of a cut part 204, the width of the cut part 204, the material of the spring part 200, the extent of heat treatment, and the overall length of the spring part 200 are set to adjust the elastic force required for the probe.

Further, a bottom end 206 corresponding to the end of the coil spring is open, as shown in FIG. 3a. Thus, preferably, the lower surface of the bottom end 206 is ground to be flat, or the winding number of the coil spring is adjusted, thus preventing bending due to vertical load. Further, as shown in FIG. 3b, the cut part 204 may not be formed in the lower portion of the spring part 200, and thus the entire lower surface can bear a vertical load.

A locking step 104 will be described below in detail.

The locking step 104 is provided on the outer circumferential surface of the probe part 100, and is restrained by a test socket.

In order to prevent the probe pressed by pressing force from moving to the outside, the locking step 104 is provided along the outer circumferential surface of the probe part 100 to be restrained by the test socket.

FIG. 4 is a sectional view showing the state where the test probe according to the preferred embodiment of the present invention is mounted to the test socket.

As shown in the drawing, the probe is restrained by the socket 3, and a pressing part (not shown) installed in the socket 3 presses the microchip downwards, so that the microchip contacts the probe part of the probe.

When the probe part 100 contacts the microchip, the spring part 200 of the probe elastically moves downwards. When the test has been completed, the probe is moved upwards by elastic restoring force. At this time, the probe is restrained in the socket 3 by the engagement of the socket 3 with the locking step provided on the outer circumferential surface of the probe part 100.

A test probe equipped with a lower plunger according to another embodiment of the present invention will be described below.

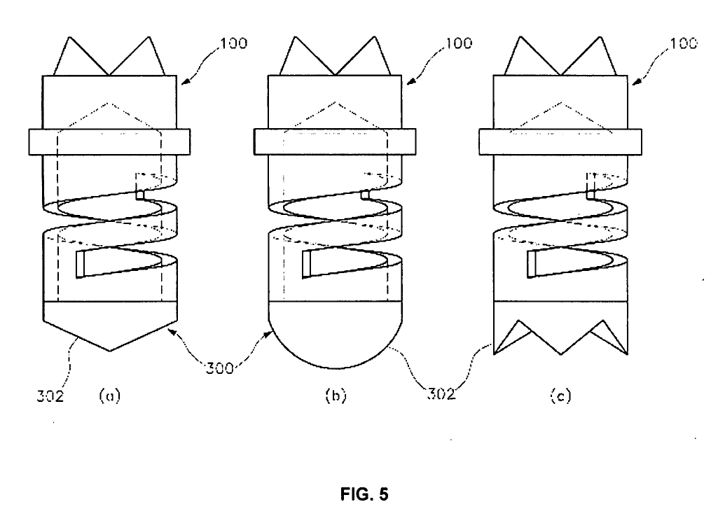

FIGS. 5a to 5c are front views showing the test probe equipped with the lower plunger according to the preferred embodiment of the present invention.

As shown in the drawings, a lower plunger 300 is coupled to the lower portion of a spring part 200, so that current flows from an object to be tested to the lower portion of the lower plunger 300. Preferably, the lower plunger 300 includes a cylindrical body coupled to the spring part 200, and at least one contact protrusion 302 which is provided on the lower portion of the cylindrical body.

As shown in the drawings, the contact protrusion 302 is manufactured to have a hemispherical shape or an inverted conical shape. Further, the contact protrusion 302 may comprise a plurality of contact protrusions. As such, the contact protrusion may be manufactured in various shapes.

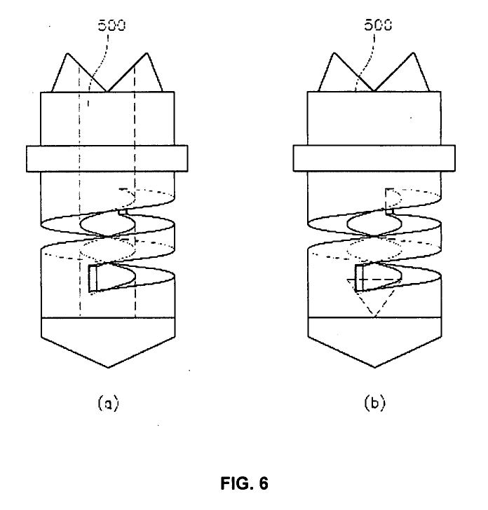

FIGS. 6a and 6b are front views showing the shape of the spring part, according to the preferred embodiment of the present invention.

Unlike the former embodiment, the spring part may have a hollow part 500 which passes through a cylindrical probe part, as shown in FIG. 6a. The spring part may have a hollow part 500 which is formed in a direction from an upper portion to a lower portion, as shown in FIG. 6b.

As described above, the spring part is manufactured in the shape of the coil spring by cutting the outer circumferential surface of the hollow part.

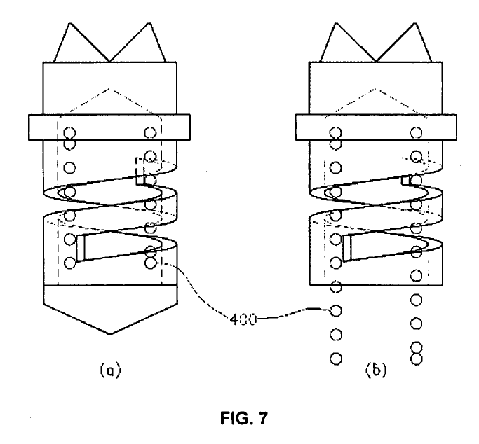

FIGS. 7a and 7b are front views showing the state where an elastic member is coupled to the spring part, according to the preferred embodiment of the present invention.

As shown in the drawings, the elastic member 400 is provided in the hollow part 500, thus providing elastic force when the probe part contacts the chip. The elastic member 400 is a component that complements the elastic force of the spring part. Preferably, the elastic member 400 comprises a general compression coil spring.

As shown in FIG. 7a, the elastic member 400 is coupled to the hollow part 500 of the probe part 100 and is held by the lower plunger 300. Alternatively, as shown in FIG. 7b, the elastic member 400 may be manufactured so that the upper portion of the elastic member 400 is coupled to the hollow part 500, and the lower portion thereof protrudes out of the probe part 100.

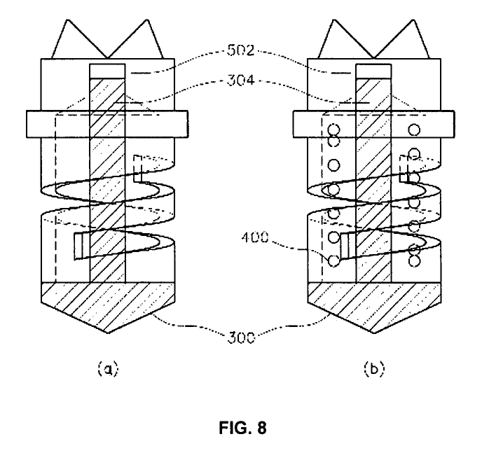

FIGS. 8a and 8b are front views showing a contact protrusion provided on the lower plunger 300, according to the preferred embodiment of the present invention.

As shown in the drawings, a guide shaft 304 is provided in the center of the lower plunger 300 in such a way as to extend upwards. A shaft hole 502 is formed in the upper portion of the hollow part 500 defined in the cylindrical probe part 100, and thus the guide shaft 304 is inserted into the shaft hole 502.

The guide shaft 304 functions to prevent the probe part 100 coupled to the spring part 200 from being distorted when the probe part 100 moves up and down. Preferably, the guide shaft 304 is provided in the elastic member 400, as shown in FIG. 8b.

As shown in the drawings, the guide shaft 304 may be manufactured to have a circular or polygonal shape. Preferably, the guide shaft 304 is spaced apart from the upper surface of the shaft hole 502 by a predetermined interval to allow the probe part 100 to move up and down when the probe contacts a semiconductor chip.

The method of manufacturing the test probe according to the present invention will be described in the following.

According to the present invention, the test probe has on the upper portion thereof the probe part having a plurality of protrusions which contact the contact terminal of the object to be tested. The spring part is integrally provided on the lower portion of the probe part. The method of manufacturing the test probe includes forming a hollow shaft by forming a hollow part in a solid shaft extending downwards from the cylindrical probe part, and cutting an outer circumferential surface of the hollow shaft at a predetermined lead angle, thus making a coil spring out of the outer circumferential surface of the hollow shaft.

Further, the method of manufacturing the test probe includes coupling the lower plunger to a lower portion of the coil spring.

The forming the hollow shaft includes forming the hollow shaft by forming a hollow part passing through the cylindrical probe part, or by drilling an upper or lower portion of the cylindrical probe part.

Since the prior art related to the method of manufacturing the probe part is already known, a detailed description thereof will be omitted.

First, in order to form the hollow shaft, the hollow part is formed by drilling the probe part 100, which is a solid shaft having a predetermined length. Depending on the thickness of the formed hollow shaft, the elastic force of the spring part is variable. Thus, it is preferable to adjust the thickness of the hollow shaft to realize the required elastic force. As shown in FIGS. 6a and 6b, when the hollow part is formed by boring the probe part 100 or is formed in the upper portion of the probe part 100, the protrusion 102 provided on the upper portion of the probe part 100 may be broken or damaged. Therefore, it is more important to adjust the thickness of the hollow shaft.

Further, the step of forming the hollow shaft includes forming the hollow part in the solid shaft extending from the lower portion of the cylindrical probe part, and forming the shaft hole in the upper surface of the hollow part so that the guide shaft is inserted into the shaft hole. The guide shaft extends upwards from the lower plunger.

In order to form the shaft hole 502, into which the guide shaft 304 provided on the lower plunger 300 is inserted, preferably, the hollow part 500 is formed in the lower portion of the probe part 100, and thereafter the shaft hole 502 is formed using a drill.

Next, the cut part having a predetermined lead angle is formed in the hollow shaft. The cut part 204 is cut on the outer circumferential surface of the hollow shaft at a predetermined lead angle. By adjusting the width of the cut part 204, the elastic force of the spring part may be adjusted.

Finally, the step of coupling the lower plunger is executed. The lower plunger is coupled to the lower surface of the spring part 200. In the case of the lower plunger having the guide shaft 304, the guide shaft 304 is coupled to the shaft hole 502 formed in the upper surface of the hollow part 500.

In this case, the guide shaft 304 is spaced apart from the upper portion of the shaft hole 502 by a predetermined interval. Thereby, when the probe part 100 is moved up and down by a vertical load generated during the test of the chip, the guide shaft 304 is restrained in the shaft hole 502.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

As described above, the present invention provides a test probe and a method of manufacturing the test probe, in which a spring part is integrally provided on the lower portion of a probe part, thus having a simple structure and affording ease of manufacture, and in which measuring current is transmitted directly from the probe part to the spring part, thus eliminating contact resistance and shortening the signal path, therefore enhancing the reliability of a test.

1. A test probe, comprising:
a probe part provided on an upper portion of the probe, and contacting a contact terminal of an object to be tested; and
a spring part providing elastic force and extending integrally from a lower portion of the probe part, so that current flows from the object to a lower portion of the spring part.

2. The test probe as set forth in claim 1, wherein a lower plunger is coupled to the lower portion of the spring part, so that current flows from the object to a lower portion of the lower plunger.

3. The test probe as set forth in claim 1, wherein the probe part comprises:
a locking step provided along an outer circumferential surface of the probe part, and engaging with a test socket.

4. The test probe as set forth in claim 1, wherein the spring part comprises a coil spring made by forming a hollow part in the lower portion of the cylindrical probe part and cutting an outer circumferential surface of the hollow part at a predetermined lead angle.

5. The test probe as set forth in claim 1, wherein the spring part comprises a coil spring made by forming a hollow part passing through the cylindrical probe part and cutting an outer circumferential surface of the hollow part at a predetermined lead angle.

6. The test probe as set forth in claim 1, wherein the spring part comprises a coil spring made by drilling an upper portion of the cylindrical probe part to form a hollow part and cutting an outer circumferential surface of the hollow part at a predetermined lead angle.

7. The test probe as set forth in claim 1, wherein the spring part has therein an elastic member for providing elastic force to the spring part.

8. The test probe as set forth in claim 2, wherein a guide shaft is provided in a center of the lower plunger and extends upwards, and a shaft hole is formed in an upper portion of the hollow part defined in the cylindrical probe part so that the guide shaft is inserted into the shaft hole.

9. The test probe as set forth in claim 2, wherein the lower plunger comprises:
a cylindrical body coupled to the spring part; and
at least one contact protrusion provided on a lower portion of the cylindrical body.

10. The test probe as set forth in claim 9, wherein the contact protrusion has an inverted conical shape.

11. The test probe as set forth in claim 9, wherein the contact protrusion has a hemispherical shape.

12. A method of manufacturing a test probe including a probe part which is provided on an upper portion thereof and has a plurality of protrusions contacting a contact terminal of an object to be tested, and a spring part integrally provided on a lower portion of the probe part, the method comprising:
forming a hollow shaft by forming a hollow part in a solid shaft extending downwards from the cylindrical probe part; and
cutting an outer circumferential surface of the hollow shaft at a predetermined lead angle, thus making a coil spring out of the outer circumferential surface of the hollow shaft.

13. A method of manufacturing a test probe including a probe part which is provided on an upper portion thereof and has a plurality of protrusions contacting a contact terminal of an object to be tested, a spring part integrally provided on a lower portion of the probe part, and a lower plunger, the method comprising:
forming a hollow shaft by forming a hollow part in a solid shaft extending downwards from the cylindrical probe part;
cutting an outer circumferential surface of the hollow shaft at a predetermined lead angle, thus making a coil spring out of the outer circumferential surface of the hollow shaft; and
coupling the lower plunger to a lower portion of the coil spring.

14. The method as set forth in claim 12, wherein the forming the hollow shaft comprises forming the hollow shaft by forming a hollow part passing through the cylindrical probe part.

15. The method as set forth in claim 12, wherein the forming the hollow shaft comprises forming a hollow part by drilling an upper portion of the cylindrical probe part.

16. The method as set forth in claim 12, wherein the forming the hollow shaft comprises:
forming a hollow part in a solid shaft extending downwards from the cylindrical probe part; and
forming a shaft hole in an upper surface of the hollow part so that a guide shaft extending upwards from the lower plunger is inserted into the shaft hole.

17. The method as set forth in claim 13, wherein the forming the hollow shaft comprises forming the hollow shaft by forming a hollow part passing through the cylindrical probe part.

18. The method as set forth in claim 13, wherein the forming the hollow shaft comprises forming a hollow part by drilling an upper portion of the cylindrical probe part.

19. The method as set forth in claim 13, wherein the forming the hollow shaft comprises:
forming a hollow part in a solid shaft extending downwards from the cylindrical probe part; and
forming a shaft hole in an upper surface of the hollow part so that a guide shaft extending upwards from the lower plunger is inserted into the shaft hole.
